(19) United States
(12) Patent Application Publication
(10) Pub. No.: US 2024/0134281 A1
(43) Pub. Date: Apr. 25, 2024

(54) EUV-INDUCED CONDENSATION OF POLYSILOXANE SOL-GEL THIN FILM

(71) Applicant: Brewer Science, Inc., Rolla, MO (US)

(72) Inventor: Daniel Patrick Sweat, Rolla, MO (US)

(21) Appl. No.: 18/483,118

(22) Filed: Oct. 9, 2023

Related U.S. Application Data
(60) Provisional application No. 63/414,270, filed on Oct. 7, 2022.

(51) Int. Cl. G03F 7/075; G03F 7/16; G03F 7/20; G03F 7/34

(52) U.S. Cl. CPC G03F 7/0755; G03F 7/168; G03F 7/2004; G03F 7/346; G03F 7/32

(57) ABSTRACT

Methods for direct patterning of a silicon hardmask with extreme ultraviolet (EUV) radiation are provided. The method involves forming a polysiloxane and/or oligosiloxane composition into a silicon hardmask layer followed by solvent removal. Without using a photoresist and/or other layer silicon hardmask layer, condensation of the siloxane sol-gel polymers and/or oligomers is induced by EUV radiation, rendering the exposed portions insoluble in typical lithography solvents or developers. The exposed portions of the silicon hardmask layer are removed, leaving a pattern in the silicon hardmask layer that can be transferred to any layers below the silicon hardmask layer, and ultimately to the substrate.

### CROSS-REFERENCE TO RELATED APPLICATIONS

The present application claims the priority benefit of U.S. Provisional Patent Application Ser. No. 63/414,270, filed Oct. 7, 2022, entitled EUV-INDUCED CONDENSATION OF POLYSILOXANE SOL-GEL THIN FILM, the entirety of which is incorporated by reference herein.

### BACKGROUND

### Field

The present disclosure relates to methods of fabricating microelectronic structures using lithography.

### Description of Related Art

For patterning applications using extreme ultraviolet (EUV) lithography, two major approaches are typically used. One approach involves replacing the photoresist of a conventional tri-layer patterning stack with a chemically amplified (CAR) photoresist. Under this approach, the substrate is coated with a carbon-rich organic layer, and a silicon-containing hardmask is formed on top of the carbon-rich layer. A photoresist is applied to the carbon-rich layer as the top layer of the stack, and the photoresist is patterned by exposure to EUV radiation through a reticle containing the desired pattern. After exposure, the stack is baked followed by a developer rinse to reveal the exposed pattern. After the develop and rinse steps, the stack is baked again. This process transfers the reticle pattern into the photoresist, where the exposed area is developer-soluble for a positive-tone photoresist or insoluble in developer for a negative tone photoresist. The CAR photoresist pattern is then transferred into the hardmask with a dry etch process using typical silicon hardmask etch plasma chemistry (CF₄, CHF₃, SF₆, Cl₂) after which the hardmask pattern is transferred into the carbon-rich layer with a dry etch process using a typical organic material etch plasma chemistry (O₂, N₂/H₂). Finally, the pattern is transferred into the substrate using plasma chemistry optimized for the particular substrate.

The second approach is to use a metal oxide photoresist (MOR). Similar to the tri-layer approach, the substrate is coated with a carbon-rich organic layer, the major role of which is to provide sufficient etch selectivity versus the substrate to allow pattern transfer of the desired aspect ratio into the substrate. A thin EUV underlayer (UL) is applied on top of the carbon-rich layer. The EUV UL is designed to provide chemical compatibility with the MOR and to prevent metal (such as tin) from diffusing into the carbon-rich organic layer. The EUV UL is a critical layer, because any metal ions/particles that diffuse into the carbon-rich organic layer may form clusters that will act as etch block defects during pattern transfer into the carbon-rich organic layer. The MOR, which is the top layer of the stack, is exposed to EUV radiation through a reticle containing the desired pattern. After exposure, the stack is baked followed by a developer rinse and then baked again. This process transfers the reticle pattern into the photoresist where the exposed area is insoluble in the developer, as the MOR is a negative-tone photoresist. The MOR pattern is transferred into the EUV UL and carbon-rich organic layer with a dry etch process using typical organic material etch plasma chemistry (O₂, N₂/H₂). In the case of an inorganic EUV UL, an additional etch step may be required. Finally, the pattern is transferred into the substrate using plasma chemistry optimized for a given substrate.

Each of the CAR and MOR approaches is costly and complex. Thus, there is a need for EUV lithography processes that simplify the complexities of both approaches, and that can be carried out with a comparatively reduced cost of ownership.

### SUMMARY

In one embodiment, the present disclosure is broadly concerned with a method of forming a structure, where the method comprises forming a silicon hardmask layer comprising a siloxane on a stack and selectively exposing the silicon hardmask layer to EUV radiation so as to induce condensation of the siloxane. The siloxane is chosen from polysiloxanes, oligosiloxanes, or both, and the siloxane comprises monomers chosen from tetraethoxysilane, methyltrimethoxysilane, isobutyltri-methoxy silane, phenyltrimethoxysilane, nonafluorohexyltriethoxysilane, 2-(3,4-epoxycyclohexyl)-ethyltrimethoxysilane, or combinations thereof.

In another embodiment, the disclosure provides a structure comprising:
a substrate comprising a surface;
optionally one or more intermediate layers on the substrate surface, there being an uppermost intermediate layer on the substrate surface, if one or more intermediate layers are present; and
a silicon hardmask layer on the substrate surface, or on the uppermost intermediate layer, if present.
   The silicon hardmask layer comprises a siloxane, first areas comprising condensed siloxane, and second areas comprising uncondensed siloxane. The siloxane comprises a polysiloxane, an oligosiloxane, or both, with the siloxane further comprising monomers chosen from tetraethoxysilane, methyltrimethoxysilane, isobutyltrimethoxysilane, phenyltrimethoxysilane, nonafluorohexyltri-ethoxysilane, 2-(3,4-epoxycyclohexyl)ethyltrimethoxysilane, or combinations thereof.

In a further embodiment, a method of forming a structure is provided. The method comprises forming a silicon hardmask layer comprising a siloxane on a stack and selectively exposing the silicon hardmask layer to EUV radiation so as to induce condensation of the siloxane. The silicon hardmask layer further comprises a photoacid generator, and the siloxane is chosen from polysiloxanes, oligosiloxanes, or both, wherein at least one of the following is true:
(i) the siloxane does not include Si—H bonds;
(ii) the siloxane comprises at least 3 Si—O bonds per Si atom; or
(iii) the siloxane comprises at least 3 times more Si—O bonds than Si—H bonds.

In yet a further embodiment, the disclosure provides a structure comprising:
a substrate comprising a surface;
optionally one or more intermediate layers on the substrate surface, there being an uppermost intermediate layer on the substrate surface, if one or more intermediate layers are present; and
a silicon hardmask layer on the substrate surface, or on the uppermost intermediate layer, if present.
   The silicon hardmask layer comprises a siloxane, first areas comprising condensed siloxane, and second areas comprising uncondensed siloxane and a photoacid generator. The siloxane comprises a polysiloxane, an oligosiloxane, or both, and at least one of the following is true:
(i) the siloxane does not include Si—H bonds;
(ii) the siloxane comprises at least 3 Si—O bonds per Si atom; or
(iii) the siloxane comprises at least 3 times more Si—O bonds than Si—H bonds.

### BRIEF DESCRIPTION OF THE DRAWINGS

FIG. 1 is a schematic diagram (not to scale) of a process for direct EUV patterning of a silicon hardmask layer as described herein;

FIG. 2 is a scanning electron microscope (SEM) image of 36-nm lines produced as described in Example 12;

FIG. 3 contains SEM images of the formulation from Example 10 on an OptiStack® SOC120 material layer patterned as described in Example 13;

FIG. 4 contains SEM images of the formulation from Example 10 on OptiStack® SOC120 material layer looking at a 100-nm pitch L/S array, as described in Example 13;

FIG. 5 contains SEM images of the formulation from Example 10 on an experimental HT-SOC layer patterned as described in Example 13;

FIG. 6 contains SEM images of the formulation from Example 10 on an experimental HT-SOC layer looking at a 100-nm pitch L/S array, as described in Example 13;

FIG. 7 contains SEM images of the formulation from Example 11 on an experimental HT-SOC layer patterned as described in Example 13; and

FIG. 8 contains SEM images of the formulation from Example 11 on an experimental HT-SOC layer looking at a 100-nm pitch L/S array, as described in Example 13.

### DETAILED DESCRIPTION

The present disclosure is broadly concerned with photopatternable silicon hardmask compositions and methods of using those compositions to form microelectronic structures. The compositions are useful at a wide range of wavelengths but are particularly well-suited for EUV lithography processes.

### Silicon Hardmark Compositions

### 1. Polymers or Oligomers for Use in Compositions

Polymers and/or oligomers (i.e., two to ten monomers or repeat units) used in the silicon hardmask compositions herein are preferably formed by polymerizing and/or oligomerizing siloxane monomers to form a polysiloxane or oligosiloxane. Examples of suitable monomers include those chosen from methyltrimethoxysilane, methyltriethoxysilane, ethyltrimethoxy silane, propyltrimethoxysilane, isobutyltrimethoxysilane, tetraethoxysilane, phenyltrimethoxysilane, nonafluorohexyltriethoxysilane, 2-(3 ,4- epoxycyclohexyl)ethyltrimethoxysilane, (3 -glycidoxypropyl)-trimethoxysilane, (3-triethoxysilyl)propylsuccinic anhydride, 2-(carbomethoxy)ethyltri-methoxysilane, (p-chloromethyl)phenyltrimethoxysilane, phenethyltrimethoxysilane, 3-(N,N-di-methylaminopropyl)trimethoxysilane, or combinations thereof.

The polymers and oligomers are preferably synthesized using a sol-gel reaction. In an exemplary sol-gel process, the desired monomer(s) is charged to a reactor with an optional distillation apparatus or reflux setup in an appropriate polymerization solvent with stirring. The setup is preferably configured to enable the removal of methanol/ethanol byproducts through distillation during the reaction. Polymerization and oligomerization solvents include propylene glycol monomethyl ether acetate (“PGMEA”), propylene glycol methyl ether (“PGME”), acetone, propylene glycol ethyl ether (“PGEE”), cyclohexanone, ethyl lactate, 3-methyl-1,5-pentanediol, 1,2-propylene glycol, 1,3-propylene glycol, ethylene glycol, or mixtures thereof. The percent solids of the monomer(s) in the reaction mixture is preferably about 10% to about 40% by weight, and more preferably about 25% to about 35% by weight, based on the total weight of the reaction mixture taken as 100% by weight. A catalyst is then slowly charged to the reactor at a temperature of about 20° C. to about 150° C., preferably about 25° C. to about 125° C., and more preferably about 75° C. to about 105° C.

Suitable catalysts for sol-gel polymerization include those chosen from nitric acid, hydrochloric acid, acetic acid, trifluoroacetic acid, sulfonic acid, or combinations thereof. Catalyst solutions are prepared in water as about 0.001N to about 10N solutions, preferably about 0.01N to about 5N solutions, and more preferably about 3N solutions for weaker acids (i.e., pKa that is greater than 0) and about 0.01N solutions for stronger acids (i.e., pKa of about 0 or lower). These aqueous catalyst solutions are added in an amount of about 0.5 equivalents to about 20 equivalents, preferably about 2 equivalents to about 15 equivalents, and more preferably about 5 equivalents to the total monomers, where one equivalent is approximately equal to one mole of water per mol of monomer (or to about 18 grams of water per mole of monomer). The reaction mixture is stirred for about 10 minutes to about 48 hours, preferably about 1 hour to about 36 hours, and more preferably about 24 hours. The reaction is optionally performed in an inert atmosphere such as nitrogen.

Two exemplary reaction schemes are as follows:

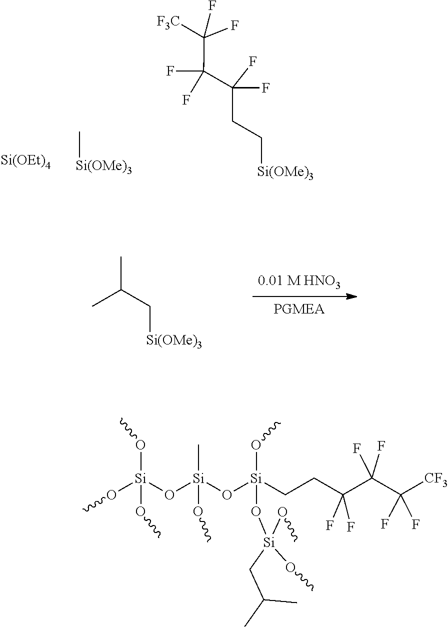

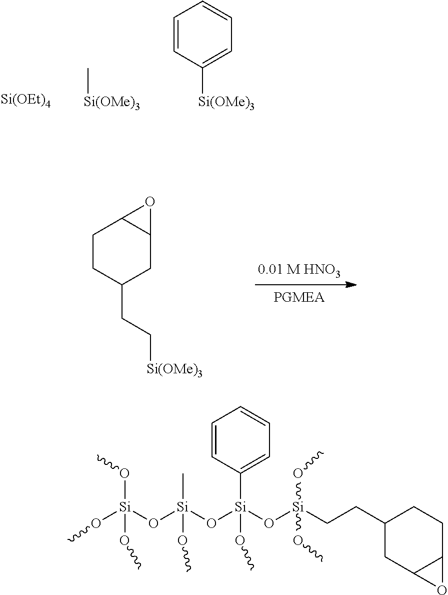

In some embodiments, the resulting polymer or oligomer has a high silicon content. That is, the polymer or oligomer preferably comprises about 20% to about 47% by weight silicon, and more preferably about 35% to about 45% by weight silicon, where the silicon percent is calculated by the molecular weight of the total silicon as a percentage of the molecular weight of the fully hydrolyzed polymer or oligomer. The weight-average molecular weight (Mw) range of the polymer is about 500 Daltons to about 50,000 Daltons, preferably about 500 Daltons to about 25,000 Daltons, more preferably about 1,000 Daltons to about 15,000 Daltons, and even more preferably about 1,000 Daltons to about 6,000 Daltons, as determined by gel permeation chromatography (GPC) using linear polystyrene standards.

In some embodiments, the polymer and/or oligomer consists essentially of, or even consists of, siloxane monomers. For example, the polymer and/or oligomer suitably consists essentially of, or even consists of, methyltrimethoxysilane, isobutyltrimethoxysilane, tetraethoxysilane, phenyltrimethoxysilane, nonafluorohexyltriethoxysilane, 2-(3,4-epoxycyclohexyl)ethyltrimethoxy-silane, or combinations thereof.

In one or more embodiments, the siloxane does not include Si—H bonds. In the same or different embodiments, the siloxane comprises at least 3, and preferably 4, Si—O bonds per Si atom. In some embodiments, the siloxane comprises at least 3 times, and preferably at least 4 times, more Si—O bonds than Si—H bonds. In some embodiments, the monomers used to form the siloxane do not contain Si—H bonds.

It is also preferred in some embodiments that the siloxane backbone (be it a polysiloxane or oligosiloxane) does not include metal atoms. In one or more embodiments, the siloxane comprises less than about 5% by weight metal, preferably less than about 3% by weight metal, more preferably less than about 1% by weight metal, and even more preferably about 0% by weight metal, based on the total weight of the siloxane taken as 100% by weight.

In some embodiments, the siloxanes are substantially or completely free of halogen atoms. For example, in these embodiments, the siloxane comprises less than about 5% by weight halogen atoms, preferably less than about 3% by weight halogen atoms, more preferably less than about 1% by weight halogen atoms, and even more preferably about 0% by weight halogen atoms, based on the total weight of the siloxane taken as 100% by weight.

### 2. Composition Preparation

The reaction mixture (mother liquor) may be formulated without further processing, or the polymer or oligomer may be isolated before using it in a final formulation. In the latter instance, the polymer and/or oligomer is dispersed or dissolved in a solvent or solvents. Preferred solvents include one or more solvents such as those chosen from PGMEA, PGME, PGEE, propylene glycol n-propyl ether (“PnP”), ethyl lactate, cyclohexanone, gamma-butyrolactone (“GBL”), 3-methyl-1,5-pentanediol, 1,2-propylene glycol, 1,3-propylene glycol, ethylene glycol, or mixtures thereof.

In one preferred embodiment, a solvent system of PGMEA and PGME is used, preferably from about 1:1 PGMEA:PGME to about 1:4 PGMEA:PGME. The solvent system is typically utilized at a level of about 80% to about 99.9% by weight, preferably about 92% to 99.5%, and more preferably about 98% to about 99% by weight, based upon the total weight of the composition taken as 100% by weight. The total solids in the composition will typically be about 0.1% to about 20% by weight, preferably about 0.5% to about 8% by weight, and more preferably about 1% to about 2% by weight, based upon the total weight of the composition taken as 100% by weight.

The compositions used to form the silicon hardmask layer will typically comprise a total polymer and/or oligomer solids content of about 0.1% to about 10% by weight, preferably about 0.1% to about 5% by weight, more preferably about 0.2% to about 2% by weight, and even more preferably about 0.3% to about 1% by weight, based upon the total weight of the composition taken as 100% by weight.

Mixing the above ingredients together in the solvent(s) forms the silicon hardmask layer composition. Furthermore, any optional ingredients (e.g., surfactants, mineral acids, organic acids, grafting/condensation catalysts, thermal acid generators (“TAGs”), photoacid generators (“PAGs”), inhibitors such as radical quenchers, and/or pH regulators), can also be dispersed in the solvent(s) at the same time.

In embodiments where a PAG is included, suitable PAGs include those chosen from triphenylsulfonium tris(trifluoromethylsulfonyl) methide, triphenylsulfonium trifluoromethane-sulfonate, triphenylsulfonium nonafluoro-1-butanesulfonate,diphenyliodonium trifluoromethane-sulfonate, diphenyliodonium nonafluoro-1-butanesulfonate, or mixtures thereof. When a PAG is utilized, the PAG will typically be included at a level of about 0.01% to about 5% by weight solids, more preferably about 0.1% to about 2.5% by weight solids, and more preferably about 0.5% to about 1.5% by weight solids, based upon the total weight of the polymer solids in the composition taken as 100% by weight.

In some embodiments, the silicon hardmask layer composition comprises less than about 0.1% by weight, preferably less than about 0.05% by weight, more preferably less than about 0.01% by weight, and even more preferably about 0% by weight siloxane condensation catalyst, based on the weight of all solids in the silicon hardmask layer composition taken as 100% by weight. Examples of siloxane condensation catalysts include benzyltriethylammonium chloride, tert-butyl phosphonium bromide, ethyltriphenylphosphonium bromide, triethoxy-3-(2-imidazolin-1-yl)propylsilane, triphenylsulfonium nitrate, acid catalysts, and base catalysts.

In one embodiment, the silicon hardmask composition consists essentially of, or even consists of, the above-described polymer and/or oligomer, one or more of the above optional ingredients, and a solvent(s).

In one or more embodiments, the silicon hardmask composition consists essentially of, or even consists of, the above-described polymer and/or oligomer, a solvent(s), and one or more of a catalyst, an acid generator, a radical inhibitor, and/or a pH regulator.

In a further embodiment, the silicon hardmask composition consists essentially of, or even consists of, the above-described polymer and/or oligomer, a solvent(s), and an acid generator.

In some embodiments, the silicon hardmask composition consists essentially of, or even consists of, the above-described polymer and/or oligomer, a solvent(s), and a PAG.

In other embodiments, the silicon hardmask composition consists essentially of, or even consists of, the above-described polymer and/or oligomer and a solvent(s).

### METHODS of USING the Silicon Hardmask Compositions

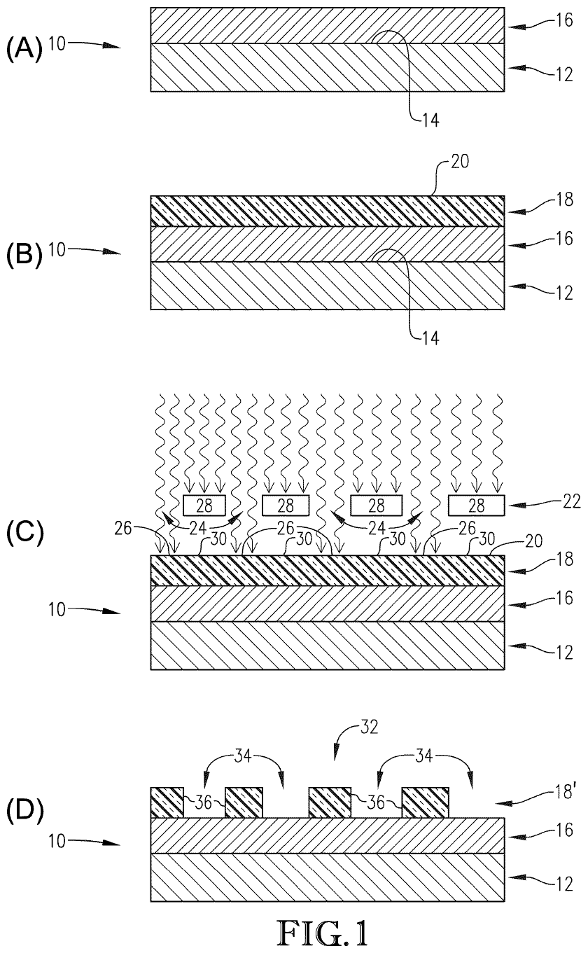

Referring to FIG. 1(A), a stack 10 is schematically depicted. Stack 10 comprises a substrate 12 having a surface 14 and optional intermediate layer(s) 16.

Substrate 12 comprises a microelectronic substrate, and preferably a semiconductor substrate. Exemplary substrates 12 comprise silicon, SiGe, SiO₂, Si₃N₄, SiON, SiCO:H (such as that sold under the name Black Diamond, by SVM, Santa Clara, CA, US), tetramethyl silate and tetramethyl-cyclotetrasiloxane combinations (such as that sold under the name CORAL), aluminum, tungsten, tungsten silicide, gallium arsenide, germanium, tantalum, tantalum nitride, Ti₃N₄, hafnium, HfO₂, ruthenium, indium phosphide, glass, or combinations of the foregoing. Surface 14 of substrate 12 can be planar, or it can include topographic features (e.g., via holes, trenches, contact holes, raised features, lines, etc.). As used herein, “topography” refers to the height or depth of a structure in or on substrate surface 14.

FIG. 1 shows a single intermediate layer 16 for illustration purposes, however, the stack 10 can include multiple intermediate layers or no intermediate layers. In some embodiments, a suitable intermediate layer 16 includes a primer layer, which can include a separate and distinct layer or a layer that is more appropriately characterized as a modification of substrate surface 14. Preferred primers include hexamethyldisilizane (“HMDS”). A primer can be formed, for example, by exposing the substrate 12 to a vapor of a primer composition in a sealed chamber while heating at about 150° C. for about 90 seconds.

Another suitable intermediate layer 16 comprises a carbon-rich layer that may be formed on substrate surface 14, or on any other intermediate layer that may be present (e.g., the primed layer or modified surface as discussed above). Carbon-rich layers include spin-on carbon (SOC) layers, amorphous carbon layers, and carbon planarizing layers. Exemplary carbon-rich layers will generally be formed from a carbon-rich composition comprising a polymer dissolved or dispersed in a solvent(s), along with one or more optional ingredients, including those chosen from acid quenchers, base quenchers, catalysts, crosslinking agents, surface modification additives, or mixtures thereof. Preferred carbon-rich compositions will be capable of being formed into relatively thick layers and thus typically have a solids content of about 0.1% to about 70% by weight, more preferably about 5% to about 40% by weight, and even more preferably about 10% to about 30% by weight, based upon the total weight of the carbon-rich composition taken as 100% by weight. The term “carbon-rich” refers to compositions and/or layers comprising greater than about 50% by weight carbon, preferably greater than about 70% by weight carbon, more preferably from about 75% to about 95% by weight carbon, and even more preferably about 75% to about 80% by weight carbon, based upon the total solids in the composition taken as 100% by weight.

The carbon-rich layer can be formed by any known application method, with one preferred method being spin-coating at speeds of about 1,000 to about 5,000 rpm, and preferably about 1,250 to about 1,750 rpm, for a time period of about 30 to about 120 seconds, preferably about 45 to about 75 seconds. After the carbon-rich composition is applied, it is preferably heated to a temperature of about 100° C. to about 400° C., and more preferably about 160° C. to about 350° C., for a time period of about 30 seconds to about 120 seconds, and preferably about 45 seconds to about 60 seconds, to evaporate solvents. The thickness of the carbon-rich layer after baking is typically about 10 nm to about 120 nm, preferably about 20 nm to about 100 nm, and more preferably about 50 nm to about 60 nm. The carbon-rich layer may also be formed by other conventional application methods, including chemical vapor deposition (“CVD”), plasma-enhanced chemical vapor deposition (“PECVD”), atomic layer deposition (“ALD”), or plasma-enhanced atomic layer deposition (“PEALD”).

Regardless of whether zero, one, two, or more intermediate layers are included in stack 10, a silicon hardmask composition as previously described can be used to form a silicon hardmask layer 18 having an upper surface 20 (FIG. 1(B)). Silicon hardmask layer 18 can be formed directly on the substrate surface 14 if no intermediate layer is utilized (not shown), on the intermediate layer 16 if only one intermediate layer is utilized (as in FIG. 1B), or on the intermediate layer that is positioned furthest from substrate surface 14 (i.e., the uppermost intermediate layer) in embodiments where multiple intermediate layers are included (not shown).

One preferred application method involves spin-coating the silicon hardmask composition at speeds of about 500 rpm to about 2,500 rpm, and preferably about 1,200 rpm to about 1,700 rpm, for a time period of about 20 seconds to about 90 seconds, and preferably about 45 seconds to about 75 seconds. After the silicon hardmask composition is applied to form silicon hardmask layer 18, layer 18 is preferably heated at a temperature sufficiently high to evaporate substantially all (about 95% or more) and preferably all (about 100%) of the solvent present in silicon hardmask layer 18. Typical temperatures for solvent removal are less than about 130° C., preferably about 40° C. to about 130° C., and more preferably about 90° C. to about 110° C., for a time period of about 30 seconds to about 90 seconds, and preferably about 45 seconds to about 75 seconds.

At the same time, it is preferable that the temperature at which the silicon hardmask layer 18 is heated be sufficiently low that condensation of the silanol groups (Si—OR, where R is individually chosen from hydrogen or C₁-C₆ alkyls) present in the polysiloxane and/or oligosiloxane is substantially, or even completely avoided. Degree of condensation can be approximated based on the change in surface contact angle of the silicon hardmask layer 18 after heating. The surface contact angle of layer 18 can be determined by averaging 5 measurements taken in different spots using an AST Optima (B5RM5208-143) contact angle measurement tool, with water as the droplet solvent. At this stage in the process, the average of 5 surface contact angle measurements is typically less than about 80, preferably less than about 60, more preferably less than about 30, even more preferably less than about 20, and most preferably less than about 10, and even more preferably less than about 5. Surface contact angle measurements in these ranges are indicative of a low to minimal degree of condensation.

In some embodiments, the change in surface contact angle measurements can be used to predict whether condensation of the silanol groups is minimized and preferably avoided during heating to remove solvent. That is, the surface contact angle (determined as previously described) of layer 18 before heating will change by less than about 20%, preferably less than about 10%, preferably less than about 5%, and more preferably by about 0% during heating to remove solvent.

The thickness of the silicon hardmask layer 18 after solvent removal is preferably about 3 nm to about 100 nm, more preferably about 4 nm to about 50 nm, even more preferably about 5 nm to about 20 nm, and most preferably about 10 nm.

It will be appreciated that a significant advantage of the disclosed processes and materials is that no photoresist or other layer need be applied on the silicon hardmask layer 18 before patterning that layer with EUV radiation, thus reducing steps and cost for the EUV lithography process. This is illustrated in FIG. 1(C), where a mask 22 is positioned above upper surface 20 of the silicon hardmask layer 18. The mask 20 has exposure portions 24 designed to permit the radiation to reflect from (in the case of EUV) or pass through (in the case of ArF or higher wavelengths) the mask and contact the surface 20 of the silicon hardmask layer 18, thus creating exposed areas 26 on and/or in silicon hardmask layer 18. Mask 22 also includes nonexposure portions 28, which are designed to absorb or block the radiation to prevent the radiation from contacting surface 20 of the silicon hardmask layer 18 in certain areas (i.e., unexposed areas 30), thus resulting in selective exposure of silicon hardmask layer 18. Those skilled in the art will readily understand that the type of mask and the arrangement of reflecting and absorbing portions (i.e., exposure portions 24 and nonexposure portions 28) is designed based upon a desired pattern to be formed in the silicon hardmask layer 18, and ultimately in any intermediate layers 16 and the substrate 12.

The exposure wavelengths are preferably about 10 nm to about 400 nm, more preferably about 13 nm to about 193 nm. In one embodiment, the layer is exposed to wavelengths of less than about 20 nm, preferably about 11 nm to about 14 nm, and more preferably about 13.5 nm, including EUV radiation. Regardless, the preferred exposure dose is about 5 mJ/cm² to about 150 mJ/cm², preferably from about 20 mJ/cm² to about 120 mJ/cm², and more preferably from about 40 mJ/cm² to about 100 mJ/cm².

EUV exposure will initiate condensation and/or crosslinking of the polysiloxane and/or oligosiloxane present in the silicon hardmask layer 18 at exposed areas 26. At this stage in the process, the average of 5 surface contact angle measurements (carried out as described previously) at exposed areas 26 is typically about 50 or greater, preferably about 60 or greater, more preferably about 70 or greater, and even more preferably about 80 or greater. Surface contact angle measurements in these ranges are indicative of a high to maximal degree of condensation. The surface contact angle measurements of unexposed areas 30 are preferably similar to those of the silicon hardmask layer 18 prior to EUV exposure, indicating the unexposed areas remain substantially uncondensed.

In some embodiments, the change in surface contact angle can be used to determine sufficient condensation of the silanol groups during EUV exposure. That is, the surface contact angle (determined as previously described) of exposed areas 26 will increase by about 20% or more, preferably about 30% or more, more preferably about 40% or more, and even more preferably about 50% or more as compared to the surface contact angle of silicon hardmask layer 18 after heating for solvent removal but prior to EUV exposure.

Silicon hardmask layer 18 preferably functions as a negative-tone development (NTD) resist. Thus, as exposed areas 26 condense, these exposed areas 26 become insoluble in typical lithography solvents (e.g., PGME, PGMEA, cyclohexanone, ethyl lactate, cyclopentanone, PGEE, ethyl lactate, GBL, 3-methoxy methyl propionate) and/or standard tetramethylammonium hydroxide (TMAH) developer, while unexposed areas 30 remain soluble in these same solvents and/or developer.

As used herein, a layer or area is considered soluble if at least about 95%, preferably at least about 98%, and more preferably about 100% by weight of the material in that area can be removed after about 20 seconds of contact with PGMEA at ambient conditions (e.g., about 22° C.). A layer or area is considered insoluble if less than about 5%, preferably less than about 2%, and more preferably about 0% by weight of the material in that area can be removed after about 20 seconds of contact with PGMEA at ambient conditions (e.g., about 22° C.). Removal can be determined by using ellipsometry to determine thickness change.

After exposure, the silicon hardmask layer 18 is optionally subjected to a post-exposure bake (PEB) at a temperature of about 60° C. to about 250° C., and preferably about 130° C. to about 205° C., for a time period of about 30 seconds to about 90 seconds, and preferably about 45 seconds to about 75 seconds. In some embodiments, the silicon hardmask layer 18 is not subjected to a post-exposure bake.

After exposure, the silicon hardmask layer 18 is contacted with a solvent or developer, such as those disclosed above, to form a pattern 32 in the silicon hardmask layer 18 (FIG. 1(D)). Specifically, the solvent or developer will remove the unexposed areas 30 of the silicon hardmask layer 18 while exposed areas 26 will not be removed by the solvent or developer. Thus, pattern 32 comprises a plurality of openings 34 (e.g., trenches, holes) along with a plurality of raised features 36 (e.g., lines, pillars). In one embodiment, the solvent used to form the pattern is selected from the group comprising PGME, PGMEA, n-butyl acetate, cyclopentanone, cyclohexanone, ethyl lactate, and combinations thereof.

After develop, patterned silicon hardmask layer 18′ is preferably subjected to a hard bake in order to promote condensation and densification at a temperature of about 160° C. to about 400° C., and preferably about 200° C. to about 300° C., for a time period of about 30 seconds to about 90 seconds, and preferably about 45 seconds to about 75 seconds.

The silicon hardmask layer 18 should have an etch rate in O₂ that is sufficient to act as an etch block and allow pattern transfer into any carbon-rich layer (if present), and/or into any other intermediate layer(s) 16. In embodiments where a carbon-rich layer is included in stack 10, that carbon-rich layer preferably etches at least about 1.5 times faster than the silicon hardmask layer 18 in an oxygen-rich (e.g., O₂) plasma etch atmosphere.

The pattern is then transferred to any intermediate layer(s) 16 that might have been included in the particular embodiment, and finally to the substrate 12. This pattern transfer can take place via plasma etching (e.g., CF₄ etchant, O₂ etchant), wet etching, or other developing process.

Regardless of whether pattern transfer is carried out by etching or developing, the resulting features have high resolutions. For example, resolutions of less than about 40 nm half-pitch, preferably less than about 20 nm half-pitch, and even more preferably less than about 16 nm half-pitch, can be achieved with the inventive method.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Synthesis of Siloxane 1

A siloxane was prepared by adding 4.25 grams of methyltrimethoxysilane (Gelest, Morrisville, PA), 3.71 grams of isobutyltrimethoxysilane (Gelest, Morrisville, PA), 10.83 grams of tetraethoxysilane (Gelest, Morrisville, PA), and 28.0 grams of propylene glycol monomethyl ether (PGME, Fujifilm Ultrapure Solutions, Carrolton, TX) to a round bottom flask and mixing thoroughly. A stir bar was added to the mixture, and while stirring, 9.45 grams of 0.01 M HNO₃ (Sigma-Aldrich, St. Louis, MO) were added dropwise over 15 minutes and stirred until the solution became homogeneous. A distillation head and condenser were added to the setup, and the reaction was heated to 95° C. for 24 hours under nitrogen. After cooling, the mixture was stored and used as a mother liquor.

### Example 2

### Formulation with Siloxane 1

In this Example, 1.0 grams of the polymer solution synthesized in Example 1, 49.9 grams of PGME, and 49.1 grams of propylene glycol monomethyl ether acetate (PGMEA, Fujifilm Ultrapure Solutions, Carrolton, TX) were added to a 100 mL Aicello bottle and mixed together for 15 minutes to generate a 0.2% (by weight) solution.

### Example 3

### Synthesis of Siloxane 2

A siloxane was prepared by adding 3.39 grams of methyltrimethoxysilane, 2.53 grams of isobutyltrimethoxysilane, 2.91 grams of nonafluorohexyltriethoxysilane (Gelest, Morrisville, PA), 5.18 grams of tetraethoxysilane, and 28.0 grams of PGMEA to a round bottom flask and mixing thoroughly. A stir bar was added to the mixture, and while stirring, 6.45 grams of 0.01 M HNO₃ were added dropwise over 15 minutes and stirred until the solution became homogeneous. A distillation head and condenser were added to the setup, and the reaction was heated to 95° C. for 24 hours under nitrogen. After cooling, the mixture was stored and used as a mother liquor.

### Example 4

### Formulation with Siloxane 2

In this Example, 1.5 grams of the polymer solution synthesized in Example 3, 20.0 grams of PGME and 78.5 grams of PGMEA were added to a 100 mL Aicello bottle and mixed together for 15 minutes to generate a 0.3% (by weight) solution.

### Example 5

### Synthesis of Siloxane 3

A siloxane was prepared by adding 2.96 grams of methyltrimethoxysilane, 2.21 grams of isobutyltrimethoxysilane, 2.82 grams of nonafluorohexyltriethoxysilane, 3.87 grams of tetraethoxysilane, and 28.0 grams of PGMEA to a round bottom flask and mixing thoroughly. A stir bar was added to the mixture, and while stirring, 5.64 grams of 0.01 M HNO₃ were added dropwise over 15 minutes and stirred until the solution became homogeneous. A distillation head and condenser were added to the setup and the reaction was heated to 95° C. for 24 hours under nitrogen. After cooling, the mixture was stored and used as a mother liquor.

### Example 6

### Formulation with Siloxane 3

In this Example, 1.5 grams of the polymer solution synthesized in Example 5, 20.0 grams of PGME and 78.5 grams of PGMEA were added to a 100 mL Aicello bottle and mixed together for 15 minutes to generate a 0.3% (by weight) solution.

### Example 7

### Synthesis of Siloxane 4

A siloxane was prepared by adding 29.01 grams of methyltrimethoxysilane, 4.76 grams of phenyltrimethoxysilane (Gelest, Morrisville, PA), 0.74 gram of 2-(3,4-epoxycyclohexyl)ethyl-trimethoxysilane (Gelest, Morrisville, PA), 12.50 grams of tetraethoxysilane, and 69.0 grams of PGMEA to a round bottom flask and mixing thoroughly. A stir bar was added to the mixture, and while stirring, 27.84 grams of 0.01 M HNO₃ were added dropwise over 1 hour and stirred until the solution became homogeneous. A distillation head and condenser were added to the setup, and the reaction was heated to 95° C. for 26 hours under nitrogen. After cooling in an ice bath, the mixture was stored and used as a mother liquor.

### Example 8

### Formulation with Siloxane 4

In this Example, 1.5 grams of the polymer synthesized in Example 7, 49.5 grams of PGME, and 49.0 grams of PGMEA were added to a 100 mL Aicello bottle and mixed together for 15 minutes to generate a 0.3% (by weight) solution.

### Example 9

### Synthesis of Siloxane 5

A siloxane was prepared by adding 8.50 grams of methyltrimethoxysilane, 3.71 grams of isobutyltrimethoxysilane, 4.33 grams of tetraethoxysilane, and 29.0 grams of PGMEA to a round bottom flask and mixing thoroughly. A stir bar was added to the mixture, and while stirring, 9.45 grams of 0.01 M HNO₃ were added dropwise over 15 minutes and stirred until the solution became homogeneous. A distillation head and condenser were added to the setup and the reaction was heated to 95° C. for 24 hours under nitrogen. After cooling, the mixture was stored and used as a mother liquor.

### Example 10

### Formulation with Siloxane 5

In this Example, 1.5 grams of the polymer synthesized in Example 9, 49.5 grams of PGME and 49.0 grams of PGMEA were added to a 100 mL Aicello bottle and mixed together for 15 minutes to generate a 0.3% (by weight) solution.

### Example 11

### Formulation with Siloxane 5 and PAG

In this Example, 1.5 grams of the polymer synthesized in Example 9, 0.3 gram of a 1% TPS-C1 (Heraeus Precious Metals North America, Vandalia, OH) in PGME solution, 49.2 grams of PGME, and 49.0 grams of PGMEA were added to a 100 mL Aicello bottle and mixed together for 15 minutes to generate a 0.3% (by weight) solution.

### Example 12

### EUV Nanopatterning

### 1. High Temperature Spin-on Carbon Composition (HT-SOC)

An experimental, HT-SOC composition was prepared as described in Example 11 of US Patent Application Publication No. US 2022/0041810 A1 (Brewer Science, Inc., Rolla, MO), the entirety of which is incorporated by reference herein. Specifically, 26.43 grams of 9,9-bis(3,4-dicarboxyphenyl)fluorene dianhydride were added to a 500-ml round-bottom flask. Next, 13.57 grams of 3-ethynylaniline (3-EA) were dissolved in 60 grams of PGME, and the solution was added to an addition funnel, which was connected to the round-bottom flask. The system was purged with nitrogen for 10 minutes, after which the 3-EA solution was added dropwise to the flask and stirred magnetically under nitrogen over a period of 4 minutes. The reaction was allowed to proceed at 50° C. under nitrogen with magnetic stirring for 8 hours. The flask was then connected to a condenser, and the reaction temperature was raised to 130° C. The imidization reaction was allowed to proceed at 150° C. under nitrogen with magnetic stirring for 16 hours.

The diimide solution was purified by precipitating in hexanes (1:5 weight ratio, Sigma Aldrich, St Louis, Mo.). The precipitated diimide was filtered and washed with hexanes (Tedia High Purity Solvents, Fairfield, Ohio) and then dried in a vacuum oven at 70° C. overnight.

### 2. Nanopatterning

The HT-SOC composition prepared in Part 1 of this Example 12 was used as an underlayer for the patterning and etch transfer process. Specifically, the HT-SOC material was coated on a 300-mm Si wafer at a 60-nm thickness by spin coating at 1,960 rpm for 60 seconds and baked at 170° C. for 60 seconds followed by a 400° C. bake for 60 seconds. The formulation from Example 8 was then coated on top of the HT-SOC with a film thickness of 10 nm by spin coating the material at 1,718 rpm for 60 seconds and then baking at 100° C. for 60 seconds.

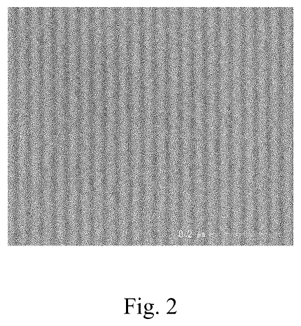

The coated wafer was exposed to EUV radiation through a reticle to define a variety of patterns and rinsed with PGMEA or a mixture of PGMEA/PGME to remove the unexposed portions. The wafer was then baked at 205° C. for 60 seconds, and the resulting patterns were examined by a Hitachi CG-6300 CD-SEM. The resolved pitch of 36-nm lines was demonstrated after the develop step. The bright lines in FIG. 2 represent the EUV-exposed silicon hardmask material after rinsing with PGMEA.

### Example 13

One wafer was prepared with a 60-nm film of OptiStack® SOC120 material (Brewer Science, Rolla, MO) by spin coating at 1,500 rpm and baking at 205° C. for 60 seconds. An additional two wafers were prepared with the HT-SOC composition described in Part 1 of Example 12.

The formulation from Example 10 was spin coated at 1,500 rpm followed by baking at 100° C. for 60 seconds on one OptiStack® SOC120 material-coated wafer and on one HT-SOC material-coated wafer, yielding 10-nm films in each instance.

The formulation from Example 11 was spin coated at 1,500 rpm followed by baking at 100° C. for 60 seconds on one HT-SOC material-coated wafer to yield a 10-nm film.

Each of the three wafers were patterned by EUV radiation of varying dose using an ASML NXE-3400 scanner with a post-exposure bake of 100° C. for 60 seconds before being developed with RER650 (70% PGMEA and 30% PGME; Fujifilm Electronic Materials, North Kingstown, RI). The resulting pattern was transferred into the SOC layer using a N₂/H₂ plasma etch and examined using top down SEM.

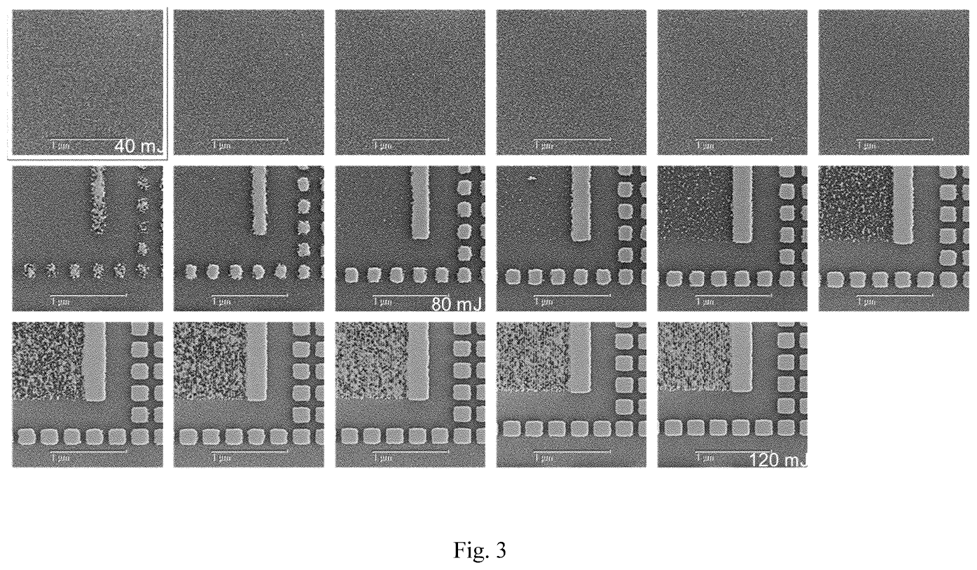

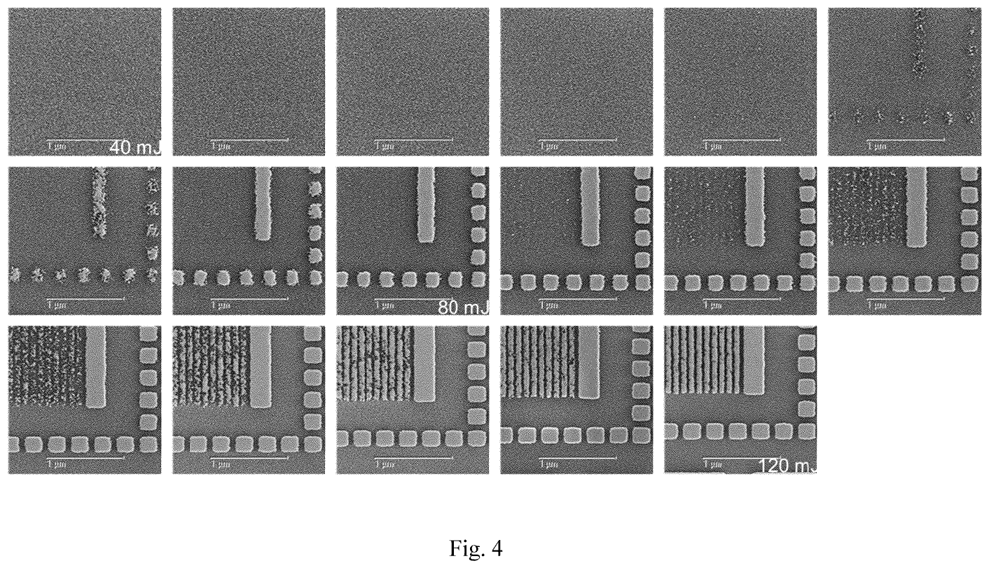

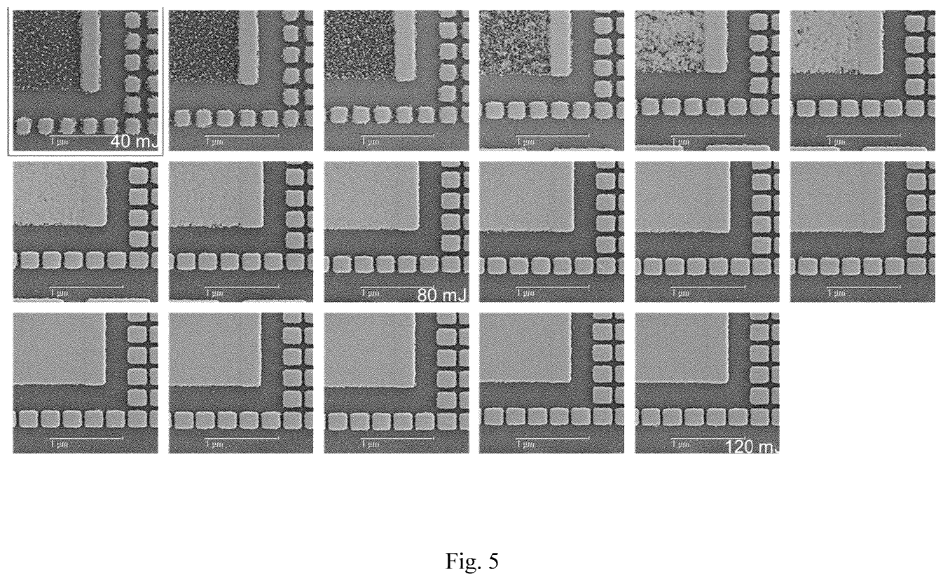

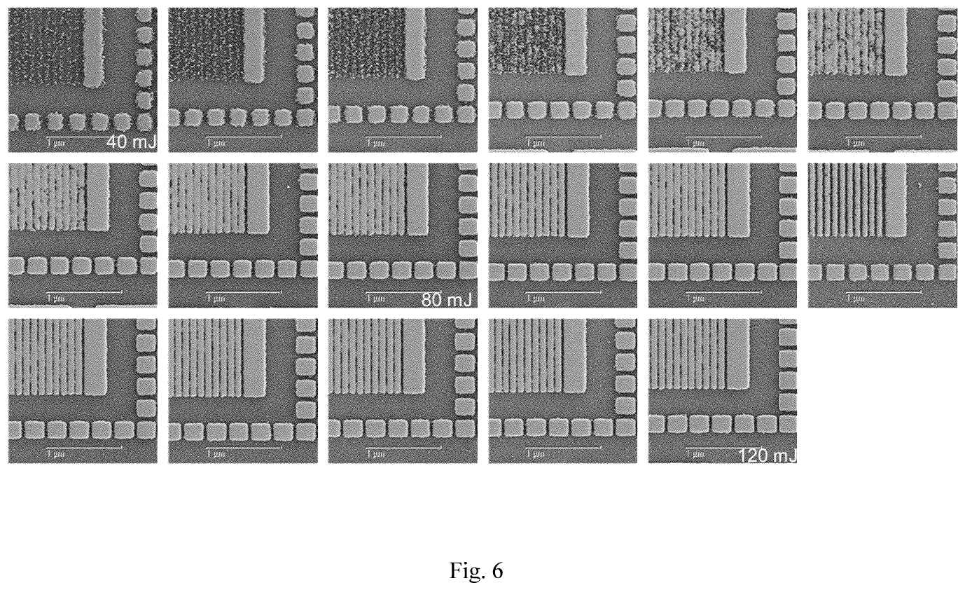

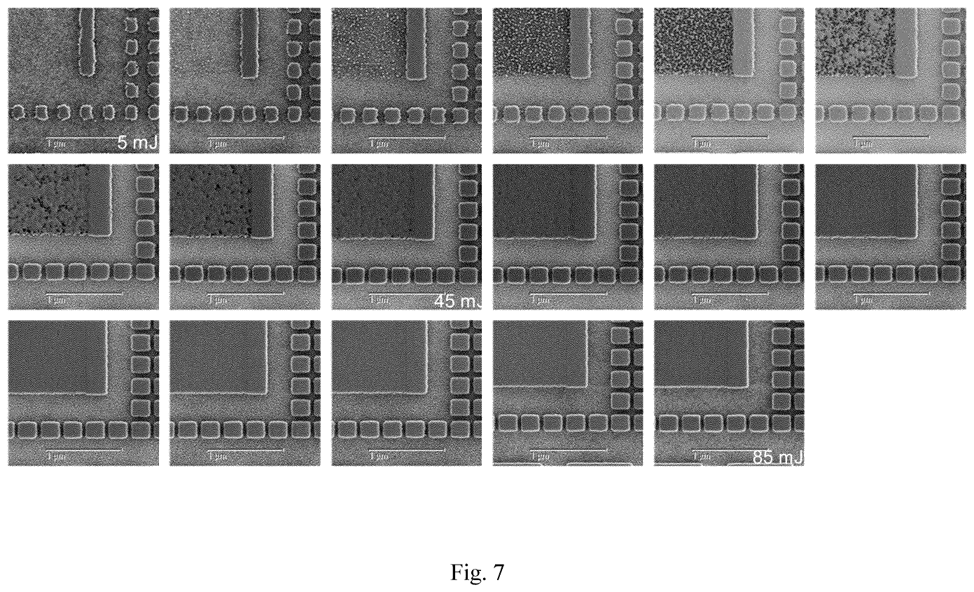

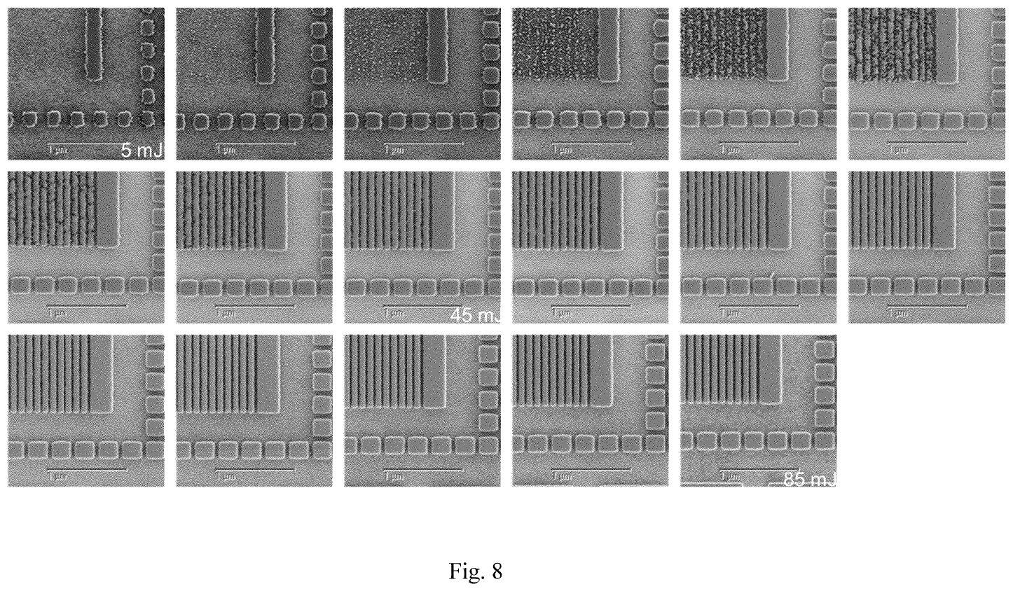

FIGS. 3-4 contain the SEMs for the Example 10 formulation on the OptiStack® SOC120 material layer. FIGS. 5-6 provide the SEMs for the Example 10 formulation on the experimental HT-SOC layer. Finally, FIGS. 7-8 show the SEMs for the Example 11 formulation on the experimental HT-SOC layer. The dose range required to pattern was reduced by the inclusion of 1% PAG in the formulation. Also, the HT-SOC material required a lower dose to pattern compared to the OptiStack® SOC120 material.

1. A method of forming a structure, said method comprising:
forming a silicon hardmask layer on a stack, said layer comprising a siloxane chosen from polysiloxanes, oligosiloxanes, or both, said siloxane comprising monomers chosen from tetraethoxysilane, methyltrimethoxysilane, isobutyltrimethoxysilane, phenyltrimethoxysilane, nonafluorohexyltriethoxysilane, 2-(3,4-epoxycyclohexyl)ethyltrimethoxysilane, or combinations thereof; and
selectively exposing said silicon hardmask layer to EUV radiation so as to induce condensation of said siloxane.

2. The method of claim 1, wherein said siloxane is in a solvent, and said forming comprises heating said silicon hardmask layer at a temperature sufficiently high to evaporate said solvent but not sufficiently high to induce condensation of said siloxane.

3. The method of claim 1, wherein said siloxane is in a solvent, and said forming comprises heating said silicon hardmask layer at a temperature of about 40° C. to about 130° C.

4. The method of claim 1, wherein said selectively exposing yields exposed areas of the silicon hardmask layer that are insoluble in propylene glycol monomethyl ether acetate and unexposed areas of the silicon hardmask layer that are soluble in propylene glycol monomethyl ether acetate.

5. The method of claim 1, said stack comprising:
a substrate having a surface; and
optionally one or more intermediate layers on said surface, there being an uppermost intermediate layer on said surface, if one or more intermediate layers are present, said silicon hardmask layer being on said uppermost intermediate layer, if present, or on said surface, if no intermediate layers are present.

6. The method of claim 5, wherein said selectively exposing forms a pattern in said silicon hardmask layer, the method further comprising transferring said pattern to any intermediate layers on said surface, and to said surface.

7. The method of claim 1, there being no additional layers on said silicon hardmask layer during said selectively exposing.

8. The method of claim 1, wherein said silicon hardmask layer optionally includes a photoacid generator, but comprises less than about 0.1% by weight total of siloxane condensation catalysts, based on the total weight of all solids in said silicon hardmask layer.

9. The method of claim 1, wherein:
(i) said siloxane does not include Si—H bonds;
(ii) said siloxane comprises at least 3 Si—O bonds per Si atom;
(iii) said siloxane comprises at least 3 times more Si—O bonds than Si—H bonds;
(iv) said siloxane comprises less than about 5% by weight metal;
(v) said siloxane comprises a backbone that does not include any metal atoms;
(vi) two of (i), (ii), (iii), (iv), or (v) are true;
(vii) three of (i), (ii), (iii), (iv), or (v) are true;
(viii) four of (i), (ii), (iii), (iv), or (v) are true; or
(ix) all of (i), (ii), (iii), (iv), or (v) are true.

10. A structure comprising:
a substrate comprising a surface;
optionally one or more intermediate layers on said substrate surface, there being an uppermost intermediate layer on said substrate surface, if one or more intermediate layers are present; and
a silicon hardmask layer on said substrate surface, or on said uppermost intermediate layer, if present, said silicon hardmask layer comprising:
a siloxane comprising a polysiloxane, an oligosiloxane, or both, said siloxane comprising monomers chosen from tetraethoxysilane, methyltrimethoxysilane, isobutyltrimethoxysilane, phenyltrimethoxysilane, nonafluorohexyltriethoxysilane, 2-(3,4-epoxycyclohexyl)ethyltrimethoxysilane, or combinations thereof;
first areas comprising condensed siloxane; and
second areas comprising uncondensed siloxane.

11. The structure of claim 10, said first areas being insoluble in propylene glycol monomethyl ether acetate and said second areas being soluble in propylene glycol monomethyl ether acetate.

12. The structure of claim 10, said substrate comprising silicon, SiGe, SiO₂, Si₃N₄, SiON, SiCO:H, tetramethyl silate and tetramethyl-cyclotetrasiloxane combinations, aluminum, tungsten, tungsten silicide, gallium arsenide, germanium, tantalum, tantalum nitride, Ti₃N₄, hafnium, HfO₂, ruthenium, indium phosphide, or glass.

13. The structure of claim 10, there being no additional layers on said silicon hardmask layer.

14. The structure of claim 10, wherein said second areas optionally include a photoacid generator, but comprise less than about 0.1% by weight total of siloxane condensation catalysts, based on the total weight of all solids in said second areas.

15. The structure of claim 10, wherein:
(i) said siloxane does not include Si—H bonds;
(ii) said siloxane comprises at least 3 Si—O bonds per Si atom;
(iii) said siloxane comprises at least 3 times more Si—O bonds than Si—H bonds;
(iv) said siloxane comprises less than about 5% by weight metal;
(v) said siloxane comprises a backbone that does not include any metal atoms;
(vi) two of (i), (ii), (iii), (iv), or (v) are true;
(vii) three of (i), (ii), (iii), (iv), or (v) are true;
(viii) four of (i), (ii), (iii), (iv), or (v) are true; or
(ix) all of (i), (ii), (iii), (iv), or (v) are true.

16. A method of forming a structure, said method comprising:
forming a silicon hardmask layer on a stack, said layer comprising:
a photoacid generator;
a siloxane chosen from polysiloxanes, oligosiloxanes, or both, wherein at least one of the following is true:
(i) said siloxane does not include Si—H bonds;
(ii) said siloxane comprises at least 3 Si—O bonds per Si atom; or
(iii) said siloxane comprises at least 3 times more Si—O bonds than Si—H bonds; and
selectively exposing said silicon hardmask layer to EUV radiation so as to induce condensation of said siloxane.

17. The method of claim 16, wherein one or both of the following is true:
(iv) said siloxane comprises less than about 5% by weight metal; or
(v) said siloxane comprises a backbone that does not include any metal atoms.

18. The method of claim 16, said siloxane comprising monomers chosen from methyltrimethoxysilane, methyltriethoxysilane, ethyltrimethoxysilane, propyltrimethoxysilane, isobutyltrimethoxysilane, tetraethoxysilane, phenyl-trimethoxysilane, nonafluorohexyl-triethoxysilane, 2-(3,4-epoxycy clohexyl)ethyltrimethoxysilane, (3-glycidoxypropyl)trimethoxysilane, (3-triethoxysilyl)propylsuccinic anhydride, 2-(carbomethoxy)ethyltri-methoxysilane, (p-chloromethyl)phenyltrimethoxysilane, phenethyltrimethoxysilane, 3-(N,N-di-methylaminopropyl)-trimethoxysilane, or combinations thereof.

19. The method of claim 16, wherein said siloxane is in a solvent, and said forming comprises heating said silicon hardmask layer at a temperature sufficiently high to evaporate said solvent but not sufficiently high to induce condensation of said siloxane.

20. The method of claim 16, wherein said siloxane is in a solvent, and said forming comprises heating said silicon hardmask layer at a temperature of about 40° C. to about 130° C.

21. The method of claim 16, wherein said selectively exposing yields exposed areas of the silicon hardmask layer that are insoluble in propylene glycol monomethyl ether acetate and unexposed areas of the silicon hardmask layer that are soluble in propylene glycol monomethyl ether acetate.

22. The method of claim 16, said stack comprising:
a substrate having a surface; and
optionally one or more intermediate layers on said surface, there being an uppermost intermediate layer on said surface, if one or more intermediate layers are present, said silicon hardmask layer being on said uppermost intermediate layer, if present, or on said surface, if no intermediate layers are present.

23. The method of claim 22, wherein said selectively exposing forms a pattern in said silicon hardmask layer, the method further comprising transferring said pattern to any intermediate layers on said surface, and to said surface.

24. The method of claim 16, there being no additional layers on said silicon hardmask layer during said selectively exposing.

25. The method of claim 16, wherein said silicon hardmask layer comprises less than about 0.1% by weight total of siloxane condensation catalysts, based on the total weight of all solids in said silicon hardmask layer.

26. A structure comprising:
a substrate comprising a surface;
optionally one or more intermediate layers on said substrate surface, there being an uppermost intermediate layer on said substrate surface, if one or more intermediate layers are present; and
a silicon hardmask layer on said substrate surface, or on said uppermost intermediate layer, if present, said silicon hardmask layer comprising:
a siloxane chosen from polysiloxanes, oligosiloxanes, or both, wherein at least one of the following is true:
(i) said siloxane does not include Si—H bonds;
(ii) said siloxane comprises at least 3 Si—O bonds per Si atom; or
(iii) said siloxane comprises at least 3 times more Si—O bonds than Si—H bonds;
first areas comprising condensed siloxane; and
second areas comprising uncondensed siloxane and a photoacid generator.

27. The structure of claim 26, wherein one or both of the following is true:
(iv) said siloxane comprises less than about 5% by weight metal; or
(v) said siloxane comprises a backbone that does not include any metal atoms.

28. The structure of claim 26, said siloxane comprising monomers chosen from methyltrimethoxysilane, methyltriethoxysilane, ethyltrimethoxysilane, propyltrimethoxysilane, isobutyltrimethoxysilane, tetraethoxysilane, phenyl-trimethoxysilane, nonafluorohexyl-triethoxysilane, 2-(3,4-epoxycy clohexyl)ethyltrimethoxysilane, (3-glycidoxypropyl)trimethoxysilane, (3-triethoxysilyl)propylsuccinic anhydride, 2-(carbomethoxy)ethyltri-methoxysilane, (p-chloromethyl)phenyltrimethoxysilane, phenethyltrimethoxysilane, 3-(N,N-di-methylaminopropyl)-trimethoxysilane, or combinations thereof.

29. The structure of claim 26, said first areas being insoluble in propylene glycol monomethyl ether acetate and said second areas being soluble in propylene glycol monomethyl ether acetate.

30. The structure of claim 26, said substrate comprising silicon, SiGe, SiO₂, Si₃N₄, SiON, SiCO:H, tetramethyl silate and tetramethyl-cyclotetrasiloxane combinations, aluminum, tungsten, tungsten silicide, gallium arsenide, germanium, tantalum, tantalum nitride, Ti₃N₄, hafnium, HfO₂, ruthenium, indium phosphide, or glass.

31. The structure of claim 26, there being no additional layers on said silicon hardmask layer.

32. The structure of claim 26, wherein said second areas comprise less than about 0.1% by weight total of siloxane condensation catalysts, based on the total weight of all solids in said second areas.
